(19) United States
(12) Patent Application Publication
(10) Pub. No.: US 2026/0169063 A1
(43) Pub. Date: Jun. 18, 2026

(54) OPTICAL DEVICES AND METHODS OF MANUFACTURE

(71) Applicant: Taiwan Semiconductor Manufacturing Co., Ltd., Hsinchu (TW)

(72) Inventors: Kuo-Hao Lee, Hsinchu (TW); Ching-Chieh Hung, Taipei (TW); You-Ting Tsai, Hsinchu (TW); Wei-Cheng Shen, Tainan City (TW); Chun-Pei Wu, Mingjian Township (TW)

(21) Appl. No.: 18/985,982

(22) Filed: Dec. 18, 2024

(51) Int. Cl. G01R 31/308; G02B 6/42

(52) U.S. Cl. CPC G01R 31/308; G02B 6/4243

(57) ABSTRACT

Devices and methods of manufacture and use of a fiber array unit are presented. In embodiments a first groove is formed within a fiber array unit substrate, the first groove having a first width adjacent to a first side of the fiber array unit substrate and a second width adjacent to a second side of the fiber array unit substrate, the first width different from the second width. A first optical fiber is placed within the first groove.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Improvements in each of these long-range optical components and short-range electrical components, along with devices used to analyze and test such devices, are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate a groove formed in a substrate, in accordance with some embodiments.

FIGS. 2A-2B illustrate optical fibers placed in grooves, in accordance with some embodiments.

FIGS. 3A-3C illustrate additional optical fibers placed in additional grooves, in accordance with some embodiments.

FIGS. 4A-4C illustrate placement of a cover plate, in accordance with some embodiments.

FIG. 5 illustrates placement of the fiber array unit into a testing device, in accordance with some embodiments.

FIGS. 6A-6B illustrate using the testing device to test a device under test, in accordance with some embodiments.

FIG. 7 illustrates forming grooves at different distances, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to a particular embodiment in which channels located within a fiber array unit are modified to adjust the angle at which individual optical fibers are placed. Such an adjustment that results in different angles for the optical fibers can be used to compensate for differences in insertion losses of each channel during a test of devices using the fiber array unit. The embodiments described herein, however, are intended to be illustrative and are not intended to be limiting. Rather, the ideas presented may be implemented in a wide variety of embodiments, and all such embodiments are fully intended to be included within the scope of the disclosure.

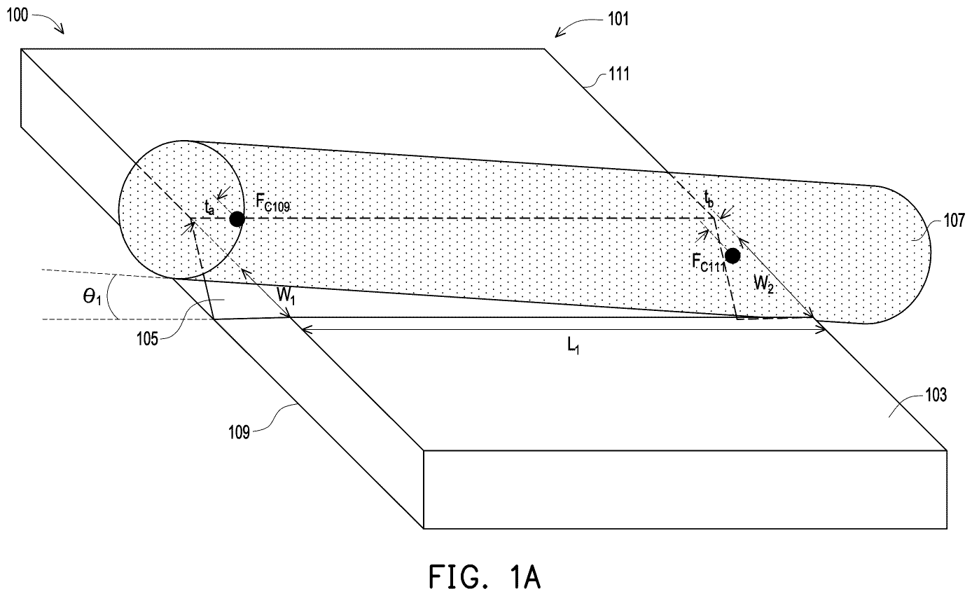

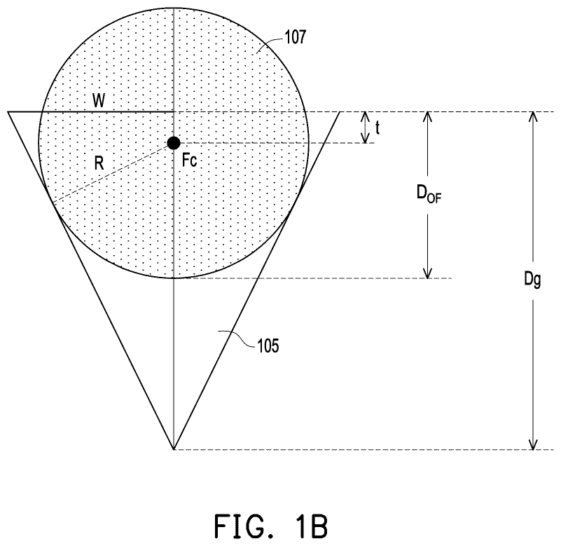

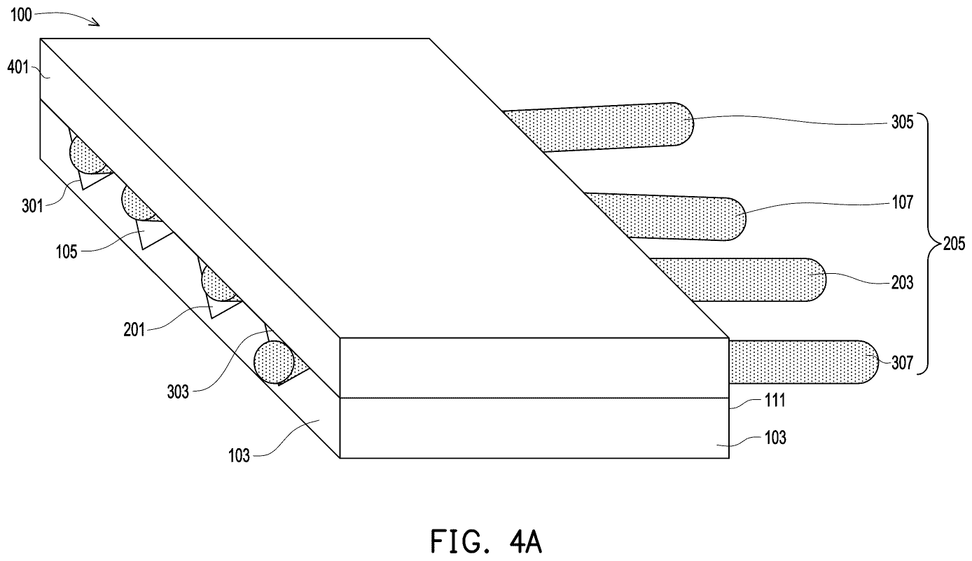

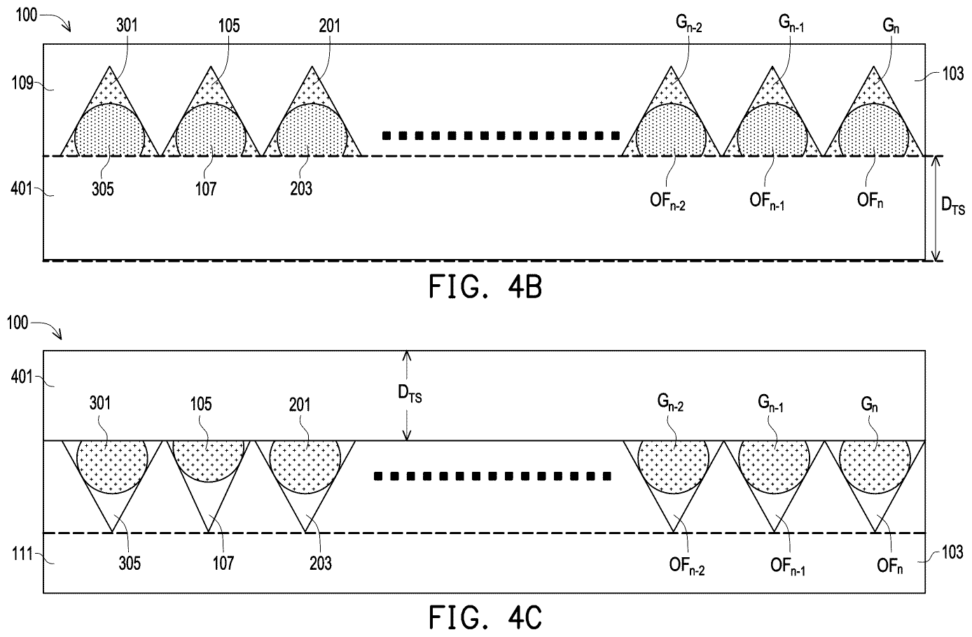

With reference now to FIG. 1A, this figure illustrates a first portion 101 with a single first optical fiber 107 of a fiber array unit 100 (not seen in totality in FIG. 1A but illustrated and discussed further below with respect to FIGS. 4A-4C). In an embodiment the first portion 101 comprises a substrate 103 with a first groove 105 that extends from a first side 109 of the substrate 103 to a second side 111 of the substrate 103. The first optical fibers 107 is placed and arranged within the first groove 105 and may be secured with an adhesive (not separately illustrated).

In an embodiment the substrate 103 comprises a support material that may also optionally function as additional cladding material for the first optical fiber 107 that will be placed within the first groove 105. In a particular embodiment the support material may be a material such as a glass, polymer, ceramic, metal, combinations of these, or the like. However, any suitable material may be utilized.

The first groove 105 is formed to extend through the substrate 103 from the first side 109 of the substrate 103 to the second side 111 of the substrate 103. In an embodiment the first groove 105 is used to control and support the first optical fiber 107 as the first optical fiber 107 extends through the substrate 103. In some embodiments the first groove 105 has at least one changing dimension as the first groove 105 extends from the first side 109 of the substrate 103 to the second side 111 of the substrate 103.

In a particular embodiment, the first groove 105 has a changing width as the first groove 105 extends from the first side 109 of the substrate 103 to the second side 111 of the substrate 103. For example, in an embodiment in which the substrate 103 has a first length L₁ of between about 1 cm and about 20 cm, the first groove 105 may have a first width W₁ adjacent to the first side 109 of the substrate 103 of between about 114 μm and about 140 μm. Additionally in this embodiment, the first groove 105 may have a second width W₂ adjacent to the second side 111 of the substrate 103 that is different from the first width W₁, such as having the second width W₂ being between about 114 μm and about 140 μm. However, any suitable dimensions may be utilized.

The first groove 105 may be formed by cutting into the substrate 103. In an embodiment the cutting may be performed using a saw blade to cut into the material of the substrate 103 (e.g., glass). In the embodiments presented herein, as the cutting process proceeds from the first side 109 of the substrate 103 to the second side 111 of the substrate 103, the substrate 103 and/or the cutting blade may be moved relative to each other in order to change the desired dimensions of the first groove 105 and obtain, for example, the first width W₁ and the second width W₂. In other embodiments the cutting tool may be shaped to obtain the desired shape of the first groove 105.

However, while a precise method of forming the first groove 105 is described above with respect to a cutting process, this is intended to be illustrative and is not intended to limit the embodiments to this precise method. Rather, any suitable method, such as forming the substrate 103 using a three-dimensional printing process, or even using one or more photolithographic masking and etching processes to form the first grooves 105 may be utilized. All such processes may be used, and are fully intended to be included within the scope of the embodiments.

The first optical fiber 107 may be placed within the first groove 105. In an embodiment the first optical fiber 107 comprises a core material such as glass surrounded by one or more cladding materials. Optionally, a surrounding cover material may be used to surround the outer cladding material in order to provide additional protection. The first optical fiber 107, either with or without the cover material, may have a first radius R₁ (seen more clearly in FIG. 1B) of between about 57 μm and about 70 μm. However, any suitable dimensions may be utilized.

Looking at FIG. 1B, FIG. 1B illustrates that the width of the first groove 105 (e.g., either the first width W₁ or the second width W₂) determines the depth D_{OF} that the first optical fiber 107 extends into the first groove 105 and, as such, determines the distance t from the surface of the substrate to the center of the channel F_{C}. As can be seen in this figure, the wider the first groove 105 is formed to be, the lower the first optical fiber 107 will sit within the first groove 105 at that width and the lower the center of the channel F_{C} will be. The precise location of the center of the channel t of the first optical fiber 107 within the first groove 105 may be determined from the following equation (Eq. 1):

$$t = {D}_{g} - \frac{R}{W} * \sqrt{{W}^{2} + {D}_{g}^{2}}$$

Wherein D_{g} is the overall depth of the first groove 105, R is the radius of the first optical fiber 107, and W is half of the width of the first groove 105 at the point of measurement.

Returning to FIG. 1A, and given this general equation for finding the precise depth of the first optical fiber 107 that is located within the first groove 105 at any point, the location tₐ of the center of the channel F_{C109} of the first optical fiber 107 at the first side 109 of the substrate 103 may be determined. In particular, the center of the channel F_{C109} of the first optical fiber 107 at the first side 109 of the substrate 103 may be found by the following equation (Eq. 2):

$${t}_{a} = {D}_{g} - \frac{R}{{W}_{1}} * \sqrt{{W}_{1}^{2} + {D}_{g}^{2}}$$

Similarly, given the general equation for finding the precise depth of the first optical fiber 107 that is located within the first groove 105 at any point, the location tb of the center of the channel F_{C111} of the first optical fiber 107 at the second side 111 of the substrate 103 may be determined. In particular, the center of the channel F_{C111} of the first optical fiber 107 at the second side 111 of the substrate 103 may be found by the following equation (Eq. 3):

$${t}_{b} = {D}_{g} - \frac{R}{{W}_{2}} * \sqrt{{W}_{2}^{2} + {D}_{g}^{2}}$$

Additionally, by forming the first groove 105 to have the different widths (e.g., the first width W₁ and the second width W₂) at different sides of the substrate 103 (e.g., the first side 109 and the second side 111), the first optical fiber 107 will lay at an angle relative to a planar surface of the substrate 103. For example, in the embodiment illustrated in FIG. 1A, the first optical fiber 107 may lay at a first angle θ₁. The first angle θ₁ may be determined (or designed for) using the following equation (Eq. 4):

$$tan {θ}_{1} = \frac{\vert {t}_{a} - {t}_{b} \vert}{{L}_{1}}$$

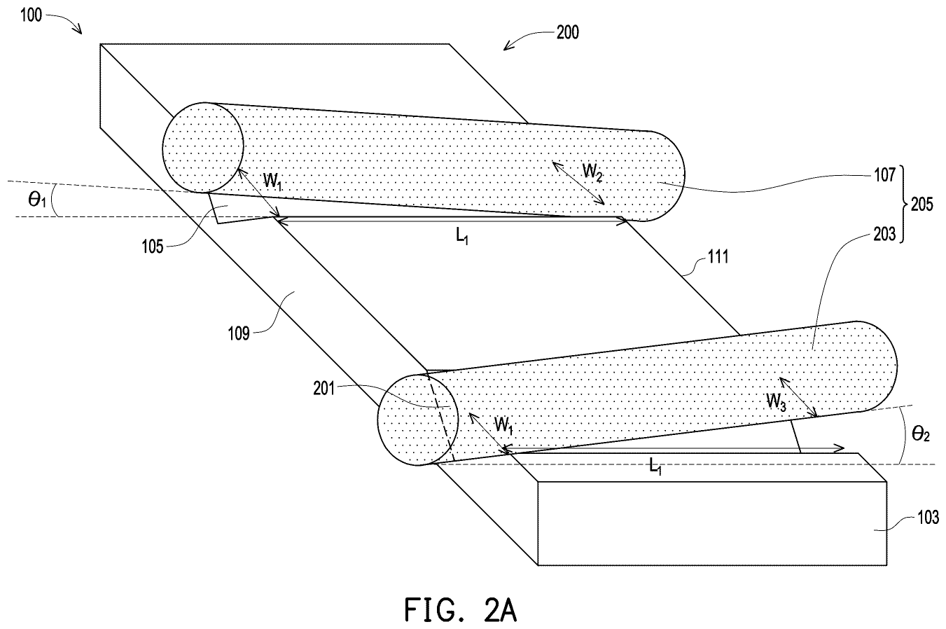

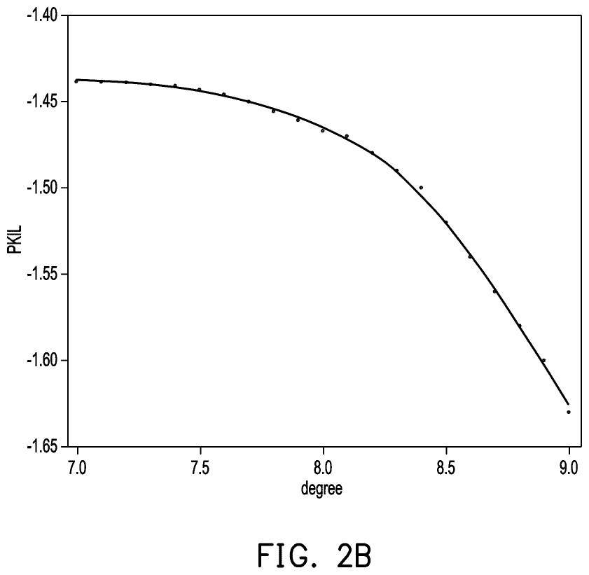

FIG. 2A illustrates a second portion 200 of the fiber array unit 100 which is an expanded view of the fiber array unit 100 with the substrate 103 and the first optical fiber 107 being located within the first groove 105. In the embodiment illustrated in FIG. 2A, a second groove 201 is also formed within the substrate 103 and a second optical fiber 203 is placed within the second groove 201. In this embodiment, the first groove 105 and the first optical fiber 107 (which collectively may be part of a plurality of optical fibers 205) may be formed and placed as described above with respect to FIGS. 1A-1B, such that the first optical fiber 107 has an induced tilt (e.g., has the first angle θ₁).

The second groove 201 and the second optical fiber 203 are, however, formed and placed in order to induce a different tilt from the first optical fiber 107. For example, while the second groove 201 may be formed as described above with respect to FIG. 1A with the first width W₁ adjacent to the first side 109 of the substrate 103, the second groove 201 may also be formed to have a third width W₃ adjacent to the second side 111 of the substrate 103. However, in this embodiment the third width W₃ is formed to be a different width from the second width W₂ (e.g., the width of the first groove 105 adjacent to the second side 111 of the substrate 103). For example, the third width W₃ may be formed to be between about 114 μm and about 140 μm. However any suitable dimensions may be utilized.

By forming the third width W₃ to be different from both the first width W₁ and the second width W₂, the second optical fiber 203, once placed within the second groove 201, will have an induced tilt (e.g., a second angle θ₂) that is different from the first optical fiber 107. In the particular embodiment illustrated in FIG. 2A, the second optical fiber 203 may even be tilted in a different direction from the first optical fiber 107, although in other embodiments the second optical fiber 203 may be tilted in the same direction as the first optical fiber 107, but to a different degree. Any suitable direction or combinations of directions may be utilized.

FIG. 2B illustrates the predicted differences in insertion losses produced by different angles that the optical fibers 205 (e.g., the first optical fiber 107 and the second optical fiber 203) may be placed. As can be seen, as the degree of tilt increases, the insertion losses can be lessened.

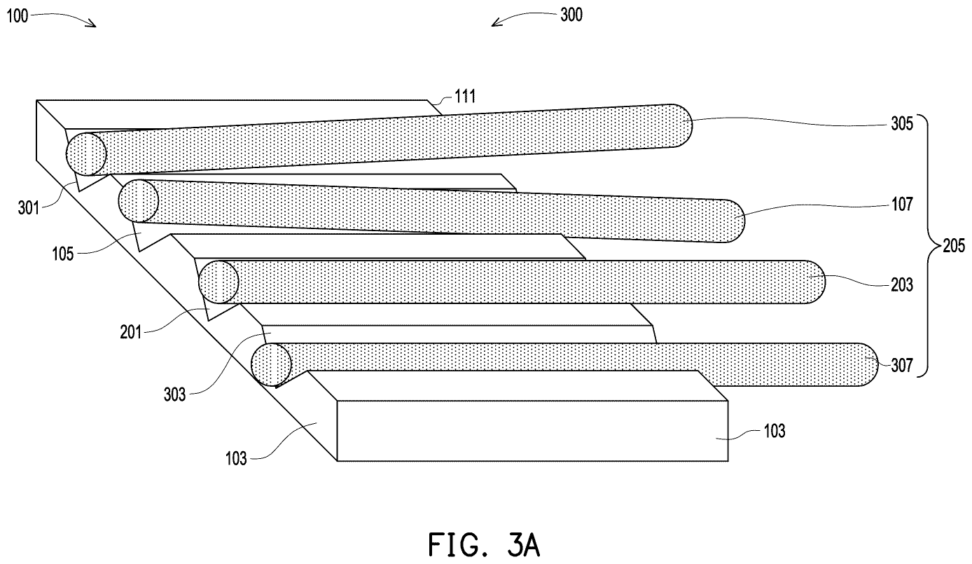

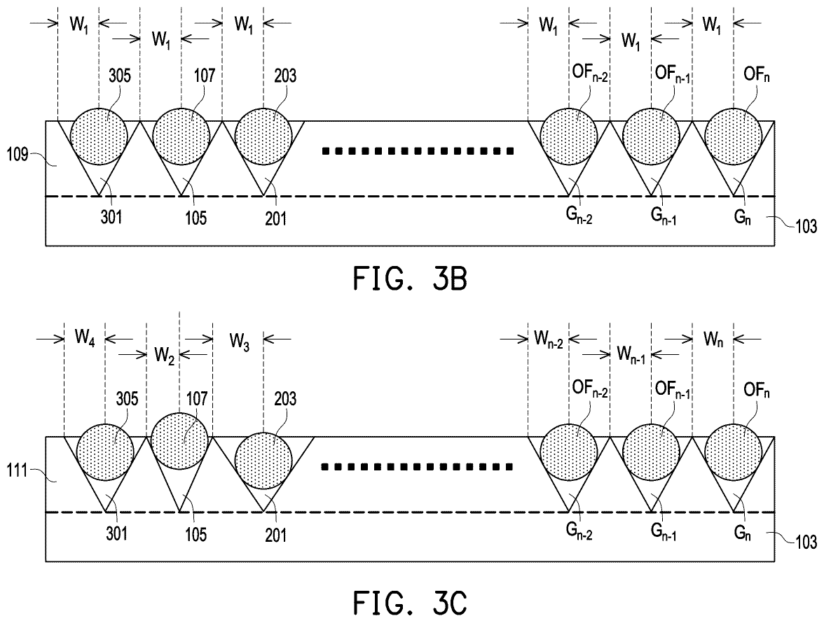

FIG. 3A illustrates a third portion 300 of the fiber array unit 100, which is a further expanded view of the fiber array unit 100 that illustrates even more of the optical fibers 205. For example, in the expanded view illustrated in FIG. 3A, the substrate 103 is formed to have the first groove 105 and the second groove 201, and is also formed to have a third groove 301 and a fourth groove 303. Also, in addition to the first optical fiber 107 (in the first groove 105) and the second optical fiber 203 (in the second groove 201), the fiber array unit illustrated in FIG. 3A has a third optical fiber 305 in the third groove 301 and a fourth optical fiber 307 in the fourth groove 303.

In this embodiment each of the first groove 105, the second groove 201, the third groove 301 and the fourth groove 303 may be formed to tune the angles of the individual optical fibers 205 (e.g., the first optical fiber 107, the second optical fiber 203, the third optical fiber 305, and the fourth optical fiber 307). For example, each of the grooves (e.g., the first groove 105, the second groove 201, the third groove 301, and the fourth groove 303) may have a width adjacent to the first side 109 of the substrate 103 that is equal to each other. However, adjacent to the second side 111 of the substrate 103 each of the grooves (e.g., the first groove 105, the second groove 201, the third groove 301, and the fourth groove 303) may have a different width from the other grooves.

FIG. 3B illustrates a cross-sectional view of the fiber array unit 100 adjacent to the first side 109 of the substrate 103. In this view, the first optical fiber 107, the second optical fibers 203, and the third optical fiber 305 are illustrated as three of the optical fibers 205 within a plurality of optical fibers (represented by the dashed line) that also includes an n−2 optical fiber OFₙ₋₂, an n−1 optical fiber OFₙ₋₁, and an n optical fiber OFₙ, wherein n is the total number of optical fibers 205, which may be between 8 and 40 optical fibers 205 (e.g., channels), such as 16 optical fibers 205 or 40 optical fibers 205. Each of the optical fibers 205 within the plurality of optical fibers 205 are located within a respective groove of the substrate 103 (e.g., the first groove 105, the second groove 201, the third groove 301, an n−2 groove Gₙ₋₂, an n−1 groove Gₙ₋₁, and an n groove Gₙ).

Additionally, in the embodiment illustrated, adjacent to the first side 109 of the substrate 103, the individual grooves have the same widths. For example, the first groove 105, the second groove 201, the third groove 301, the n−2 groove Gₙ₋₂, the n−1 groove Gₙ₋₁, and the n groove Gₙ, may each have the first width W₁. However, in other embodiments the individual grooves may have different widths from each other, or any other suitable combinations.

FIG. 3C illustrates a cross-sectional view of the fiber array unit adjacent to the second side 111 of the substrate 103, but still looking in the same direction as FIG. 3B. In this view, at the other end of the substrate 103 from the view in FIG. 3B, the first optical fiber 107, the second optical fiber 203, the third optical fiber 305, the n−2 optical fiber OFₙ₋₂, the n−1 optical fiber OFₙ₋₁, and the n optical fiber OFₙ are still located in their respective grooves of the substrate 103 (e.g., the first groove 105, the second groove 201, the third groove 301, the n−2 groove Gₙ₋₂, the n−1 groove Gₙ₋₁, and the n groove Gₙ).

Additionally, in the embodiment illustrated, adjacent to the second side 111 of the substrate 103, the individual grooves may have different widths from each other and/or the first widths W₁. For example, the first groove 105 may have the second width W₂, the second groove 201 may have the third width W₃, the third groove 301 may have a fourth width W₄, the n−2 groove Gₙ₋₂ may have an n−2 width Wₙ₋₂, the n−1 groove Gₙ₋₁, may have an n−1 width Wₙ₋₁, and the n groove Gₙ may have an n width Wₙ, wherein each of the widths are not equal to each other.

FIGS. 4A-4C illustrate further manufacturing processes in order to prepare the fiber array unit 100 for usage. In these figures, FIG. 4A illustrates a isometric view of the fiber array unit 100 of the structure illustrated in FIG. 3A, while FIG. 4B illustrates a cross-sectional view of the fiber array unit 100 adjacent to the first side 109 of the substrate 103 and FIG. 4C illustrates a cross-sectional view of the fiber array unit 100 adjacent to the second side 111 of the substrate 103. In an embodiment, once the first optical fiber 107, the second optical fibers 203, the third optical fiber 305, the fourth optical fiber 307, along with any other optical fibers 205 desired, have been placed, the first optical fiber 107, the second optical fibers 203, the third optical fiber 305, the fourth optical fiber 307, along with any other optical fibers 205 desired, may be planarized with the substrate 103. In an embodiment the planarization process may be, for example, a chemical mechanical polishing process, whereby chemical reactants and abrasives are utilized along with rotating platens in order to remove material from the first optical fiber 107, the second optical fibers 203, the third optical fiber 305, the fourth optical fiber 307. In other embodiments, other processes such as grinding processes may be used. Any suitable process may be utilized in order to planarize the optical fibers 205.

Once the optical fibers have been planarized, a cover plate 401 is attached to the substrate 103 in order to provide additional control and protection to the optical fibers. In an embodiment the cover plate 401 may comprise a material similar to or different from the material of the substrate 103. In a particular embodiment the cover plate 401 may be a material such as glass. However, any suitable material may be utilized.

The cover plate 401 may be attached to the substrate 103 over the planarized optical fibers 205. In an embodiment the cover plate 401 may be attached using an adhesive (not separately illustrated in FIGS. 4A-4C). However, in other embodiments the cover plate 401 may be attached using a bonding process. Any suitable method for attaching the cover plate 401 to the substrate 103 may be utilized, and all such methods are fully intended to be included within the scope of the embodiments.

By planarizing the optical fibers 205 and then attaching the cover plate 401, each of the optical fibers 205 are located a same first distance from the top surface DTS of the cover plate 401. In an embodiment the first distance from the top surface Drs may be between about 0.1 mm and about 0.2 mm. However, any suitable distance may be utilized.

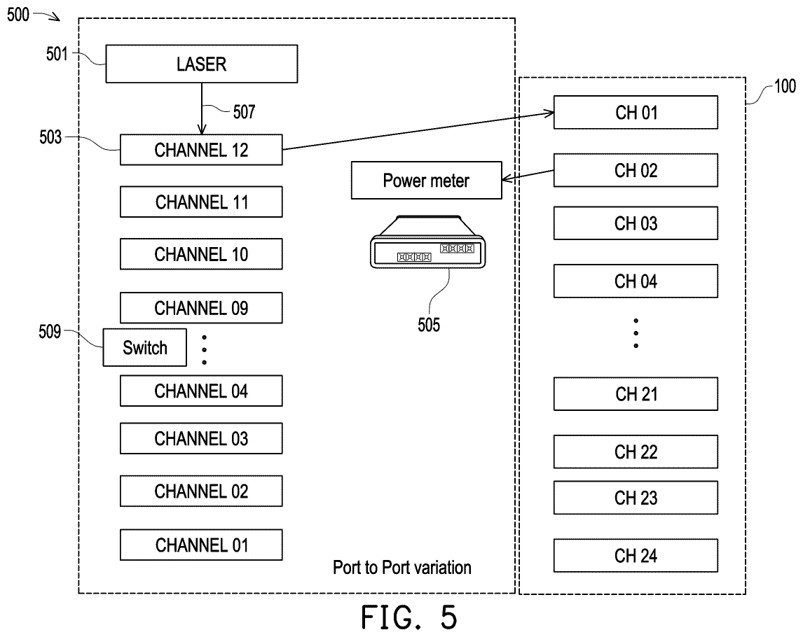

FIG. 5 illustrates a conceptual placement of the fiber array unit 100 into a test device 500. In an embodiment the test device 500 may comprise a laser 501, a plurality of channels 503 and a power meter 505. In an embodiment, the laser 501 is utilized to provide a power source and/or test signals 507 for the testing device 500. In some embodiments, the laser 501 may comprise light generating structures such as one or more laser diodes (not individually illustrated in FIG. 5). In particular embodiments the laser diodes may be Fabry-Perot Diodes, and may be based on III-V materials, II-VI materials, or any other suitable set of materials. However, any suitable structure for creating power source and/or test signals 507 may be utilized.

The plurality of channels 503 are connected to the laser 501 in order to receive the power source and/or test signals 507 generated by the laser 501 and direct the power source and/or test signals 507 to the fiber array unit 100. In an embodiment the plurality of channels 503 comprise one or more waveguides or other optical fibers, although any suitable structures or combination of structures may be utilized. Additionally, the plurality of channels 503 may comprise any suitable number of channels, such as between about 1 channel and 24 channels, such as 12 channels. However, any suitable number of channels may be utilized.

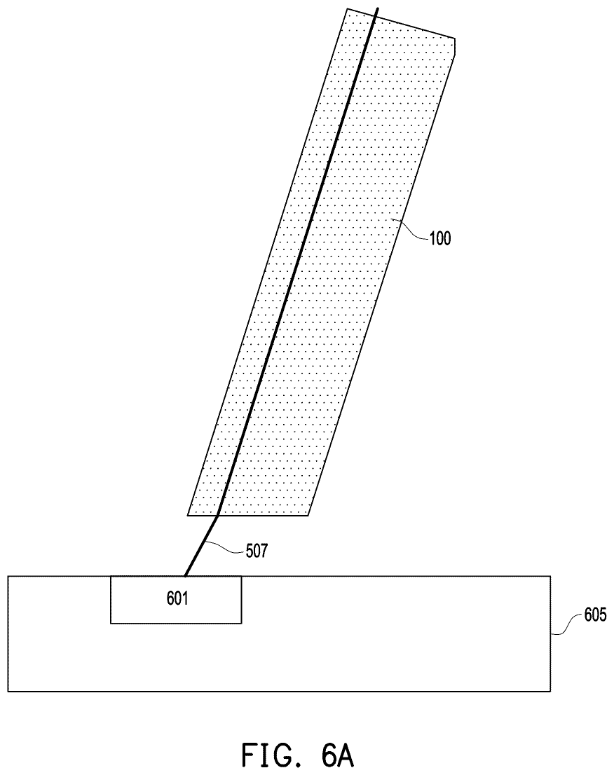

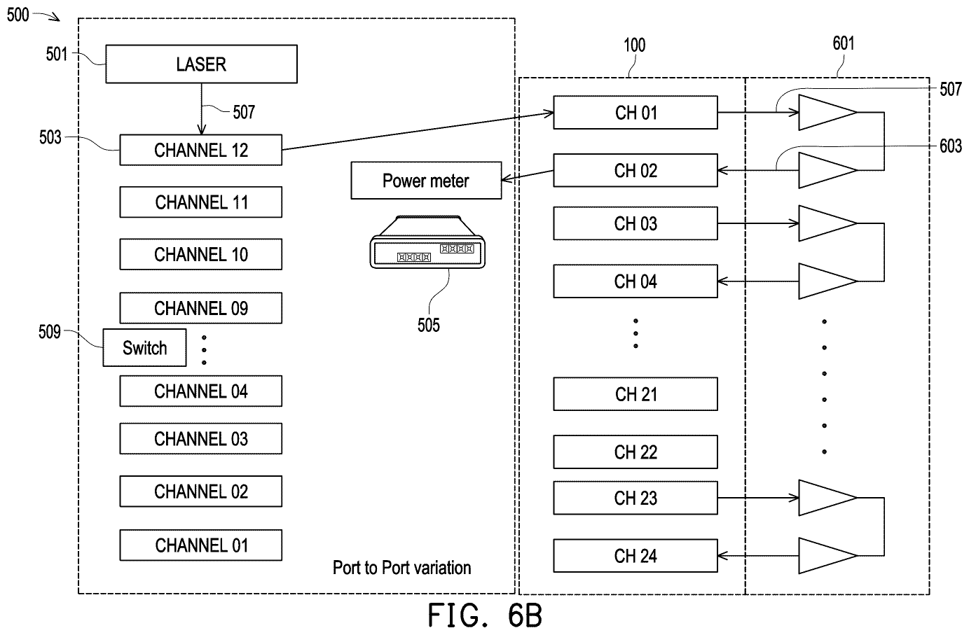

The power meter 505 is utilized to receive the power source and/or test signals 507 from a device under test (DUT—not illustrated in FIG. 5 but illustrated and discussed further below with respect to FIG. 6A) 601 by way of the fiber array unit 100. In an embodiment the power meter 505 may be a 12 channel power meter that receives the power source and/or test signals 507 and translates the power source and/or test signals 507 into test results that may be analyzed to determine if the device under test 601 has successfully completed the test.

A switch 509 may be utilized in order to connect individual ones of the plurality of channels 503 to couplers (not separately illustrated) for transmission of the power source and/or test signals 507. In an embodiment the couplers may be, for example, edge couplers designed to transmit the optical signal out of the device, with the switch 509 being used to determine which one of the plurality of channels 503 is used to transmit the power source and/or test signals 507. Additionally, the switch 509 may also be used to connect the power meter 505 to receive the power source and/or test signals 507 as the test signals 507 return from the device under test 601 through the couplers.

The fiber array unit 100 is connected to the couplers in order to send and receive the power source and/or test signals 507 to and from the device under test 601. In an embodiment the fiber array unit 100 is aligned with the couplers so that optical signals exiting the couplers are received by the optical fibers while optical signals exiting the optical fibers are received by the couplers. However, any suitable alignments and any suitable other devices may also be used in order to connect the fiber array unit 100 to the couplers and, hence, to the plurality of channels 503.

However, given all of the transitions between the various components of the testing device 500, losses in the power source and/or test signals 507 occur. For example, insertion losses can occur between the laser 501 and the plurality of channels 503, while further insertion losses can occur between the plurality of channels 503 and the optical fibers 205 within the fiber array unit 100. Additionally, while these insertion losses could be accounted for if the insertion losses were the same in each of the plurality of channels 503, the insertion losses for each individual channel within the plurality of channels 503 may be significantly different from each other.

However, by utilizing the processes described above with respect to FIGS. 1A-4C, the insertion losses for each individual channel of the plurality of channels 503 may be individually tuned by modifying the individual angles of the optical fibers 205 within the fiber array unit 100. As such, the differences in insertion losses for each channel may be individually tuned in order to minimize the differences in insertion losses, such that the insertion losses may then consistently be considered in the overall analysis.

FIGS. 6A-6B illustrate a use of the testing device 500 with the fiber array unit 100 in order to send and receive the power source and/or test signals 507 from the device under test (DUT) 601. In an embodiment the device under test 601 may be, e.g., a photonic device such as a photonic engine that is either being manufactured or has been manufactured and may still be part of a semiconductor wafer 605. However, any suitable device in any suitable phase of manufacturing, including devices already singulated, may be utilized.

During the test, the fiber array unit 100 is aligned such that the power source and/or test signals 507 leaving a first one of the optical fibers 205 within the fiber array unit 100 (e.g., the optical signals from the plurality of channels 503) are directed towards structures within the device under test 601 designed to receive the power source and/or test signals 507, such as grating couplers, edge couplers, or the like. The device under test 601 then modulates the power source and/or test signals 507 (as dictated by the design of the device under test 601) and outputs an output signal 603 to another one of the optical fibers 205 within the fiber array unit 100.

The output signal 603 is then transmitted by the fiber array unit 100 to the power meter 505. The power meter 505 detects the output signal 603 and outputs a test output (not separately illustrated). The test output is then compared to expected results and it is determined whether the device under test 601 passes or fails the test.

By utilizing the embodiments presented herein, the problems of measurement noise from differences in the optical fibers 205 may be reduced or eliminated. For example, by gradually modulating the widths of the grooves within the fiber array unit 100, the angles at which the individual optical fibers 205 are placed can be adjusted, and different angles for the individual optical fibers 205 can be used to compensate for the insertion loss of each channel. Accordingly, differences in insertion loss may be reduced from ±0.4 dB to less than about ±0.1 dB. This can be done with no extra processes or materials, and can be achieved with a single step being added or modified for the fabrication of the fiber array unit 100.

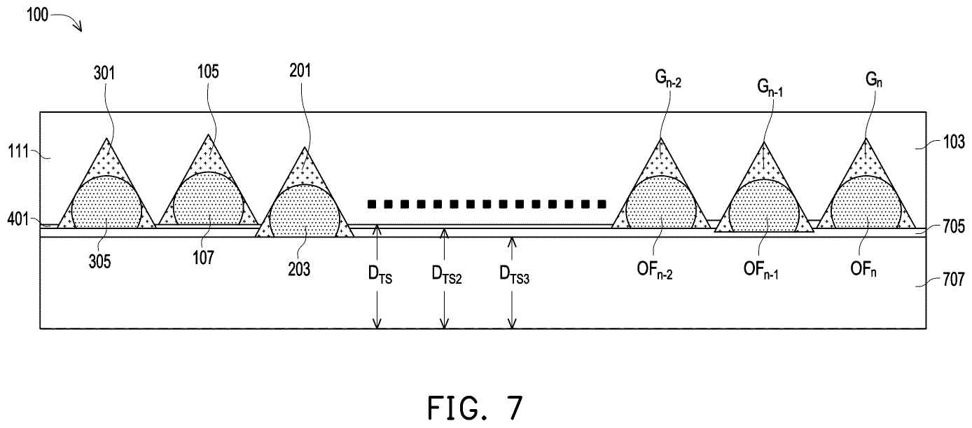

FIG. 7 illustrates another embodiment which may be used to tune the angle of the optical fibers 205 (e.g., the first optical fiber 107, the second optical fiber 203, the third optical fiber 305, etc.) within the fiber array unit 100. In this embodiment, instead of or in addition to modifying the width of the individual grooves (e.g., the first groove 105, the second groove 201, the third groove 301, etc.) within the substrate 103, the depth of the individual grooves are individually tuned as well.

In an embodiment the individual grooves may be formed at different depths by first forming a first group of the individual grooves, such as the first groove 105 illustrated in FIG. 7, into the substrate 103 and then placing optical fibers 205, such as the first optical fiber 107, into the formed grooves. In an embodiment the first group of the individual grooves may be formed and filled as discussed above with respect to FIGS. 1A-4C. For example, the first groove 105 may be formed, the first optical fiber 107 may be placed and planarized with the substrate 103. However, any suitable methods may be utilized.

Once the first group of the individual grooves (e.g., the first grooves 105 and the first optical fiber 107) have been formed, the cover plate 401 is placed over the first group of the individual grooves and then thinned to a desired thickness. In an embodiment the cover plate 401 may be attached as described above with respect to FIGS. 4A-4C, and may then be thinned using, e.g., a planarization process such as a chemical mechanical polishing process. However, any suitable processes may be utilized.

Once the cover plate 401 has been placed and thinned to the desired thickness, a second group of the individual grooves (e.g., the third groove 301, the n−2 groove Gₙ₋₂, and the n groove Gₙ in FIG. 7) may be formed. In an embodiment the second group of the individual grooves may be formed as described above with respect to FIGS. 1A-4C. However, instead of forming the second group of the grooves within just the substrate 103, the second group of the individual grooves are formed within the substrate 103 and also the cover plate 401.

Once the second group of the individual grooves have been formed, a second cover plate 705 is placed over the grooves within the second group and then thinned. In an embodiment the second cover plate 705 may be attached as described above with respect to FIGS. 4A-4C, and may then be thinned using, e.g., a planarization process such as a chemical mechanical polishing process. However, any suitable processes may be utilized.

Once the second cover plate 705 has been placed and thinned to the desired thickness, a third group of the individual grooves (e.g., the second groove 201 in FIG. 7) may be formed. In an embodiment the third group of the individual grooves may be formed as described above with respect to FIGS. 1A-4C. However, instead of forming the third group of the grooves within just the substrate 103 and the first cover plate 401, the third group of the individual grooves are formed within the substrate 103, the cover plate 401 and also the second cover plate 705.

Once the third group of the individual grooves have been formed, a third cover plate 707 is placed over the third group of the individual grooves and then thinned. In an embodiment the third cover plate 707 may be attached as described above with respect to FIGS. 4A-4C, and may then be thinned using, e.g., a planarization process such as a chemical mechanical polishing process. However, any suitable processes may be utilized.

By utilizing the process described in FIG. 7, the location and placement of the optical fibers 205 can be further tuned beyond adjusting the tilt angle of the optical fibers 205. In particular, by forming the individual grooves to have different distances from a top surface of the fiber array unit 100, further tuning of the insertion losses may be performed. For example, the first group of the individual grooves may be formed to have the first distance from the top surface DTs, while the second group of the individual grooves may be formed to have a second distance from the top surface D_{TS2} of between about 0.095 mm and about 0.195 mm, and the third group of the individual grooves may be formed to have a third distance from the top surface D_{TS3} of between about 0.093 mm and about 0.193 mm. However, any distances may be utilized in order to obtain further reductions in the differences in insertion losses.

In accordance with an embodiment, a method includes: forming a first groove within a fiber array unit substrate, the first groove having a first width adjacent to a first side of the fiber array unit substrate and a second width adjacent to a second side of the fiber array unit substrate, the first width different from the second width; and placing a first optical fiber within the first groove. In an embodiment the method further includes: forming a second groove in the fiber array unit substrate, the second groove having the first width adjacent to the first side of the fiber array unit substrate and a third width adjacent to the second side of the fiber array unit substrate, the third width being different from the first width and the second width; and placing a second optical fiber within the second groove. In an embodiment the first optical fiber is located at a first angle to a major surface of the fiber array unit substrate and wherein the second optical fiber is located at a second angle to the major surface of the fiber array unit substrate, the first angle different from the second angle. In an embodiment the method further includes planarizing the first optical fiber with the fiber array unit substrate. In an embodiment the method further includes placing a cover plate over the first optical fiber. In an embodiment the first optical fiber is located a first distance away from a top surface of the cover plate, and where the second optical fiber is located a second distance away from the top surface of the cover plate. In an embodiment the method further includes sending a test signal through the first optical fiber to a device under test.

In accordance with another embodiment, a method includes: receiving a fiber array unit substrate; forming a plurality of grooves within the fiber array unit substrate, wherein a first groove and a second groove each have a first width, wherein the first groove also has a second width, wherein the second groove also has a third width, and wherein each of the first width, the second width, and the third width are each different from each other; and placing a plurality of optical fibers into respective ones of the plurality of grooves. In an embodiment the forming the plurality of grooves comprises cutting into the fiber array unit substrate. In an embodiment the method further includes planarizing the plurality of optical fibers. In an embodiment the method further includes placing a cover plate over the plurality of optical fibers. In an embodiment a first optical fiber of the plurality of optical fibers is located a first distance away from a top surface of the cover plate, and wherein a second optical fiber of the plurality of optical fibers is located a second distance away from the top surface of the cover plate. In an embodiment a first one of the plurality of optical fibers is located at a first angle to a major surface of the fiber array unit substrate and wherein a second one of the plurality of optical fibers is located at a second angle to the major surface of the fiber array unit substrate, the first angle different from the second angle. In an embodiment the method further includes sending a test signal through one of the plurality of optical fibers to a device under test.

In accordance with yet another embodiment, an optical device includes: a substrate material with a first side and a second side; a first trench in the substrate material, the first trench having a first width adjacent to the first side of the substrate material and a second width adjacent to the second side of the substrate material, the first width different from the second width; and a first optical fiber within the first trench. In an embodiment the optical device further includes a second trench in the substrate material, the second trench having the first width adjacent to the first side of the substrate material and a third width adjacent to the second side of the substrate material, the third width being different from the first width and the second width. In an embodiment the optical device further includes a cover plate over the first trench and the second trench. In an embodiment the first trench is located a first distance away from a surface of the cover plate and wherein the second trench is located a second distance away from the surface of the cover plate, the first distance being different from the second distance. In an embodiment the first optical fiber is planar with a surface of the substrate material. In an embodiment the optical device further includes a device under test in optical communication with the first optical fiber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first groove within a fiber array unit substrate, the first groove having a first width adjacent to a first side of the fiber array unit substrate and a second width adjacent to a second side of the fiber array unit substrate, the first width different from the second width; and
placing a first optical fiber within the first groove.

2. The method of claim 1, further comprising:
forming a second groove in the fiber array unit substrate, the second groove having the first width adjacent to the first side of the fiber array unit substrate and a third width adjacent to the second side of the fiber array unit substrate, the third width being different from the first width and the second width; and
placing a second optical fiber within the second groove.

3. The method of claim 2, wherein the first optical fiber is located at a first angle to a major surface of the fiber array unit substrate and wherein the second optical fiber is located at a second angle to the major surface of the fiber array unit substrate, the first angle different from the second angle.

4. The method of claim 3, further comprising planarizing the first optical fiber with the fiber array unit substrate.

5. The method of claim 4, further comprising placing a cover plate over the first optical fiber.

6. The method of claim 5, wherein the first optical fiber is located a first distance away from a top surface of the cover plate, and where the second optical fiber is located a second distance away from the top surface of the cover plate.

7. The method of claim 1, further comprising sending a test signal through the first optical fiber to a device under test.

8. A method comprising:
receiving a fiber array unit substrate;
forming a plurality of grooves within the fiber array unit substrate, wherein a first groove and a second groove each have a first width, wherein the first groove also has a second width, wherein the second groove also has a third width, and wherein each of the first width, the second width, and the third width are each different from each other; and
placing a plurality of optical fibers into respective ones of the plurality of grooves.

9. The method of claim 8, wherein the forming the plurality of grooves comprises cutting into the fiber array unit substrate.

10. The method of claim 8, further comprising planarizing the plurality of optical fibers.

11. The method of claim 10, further comprising placing a cover plate over the plurality of optical fibers.

12. The method of claim 11, wherein a first optical fiber of the plurality of optical fibers is located a first distance away from a top surface of the cover plate, and where in a second optical fiber of the plurality of optical fibers is located a second distance away from the top surface of the cover plate.

13. The method of claim 8, wherein a first one of the plurality of optical fibers is located at a first angle to a major surface of the fiber array unit substrate and wherein a second one of the plurality of optical fibers is located at a second angle to the major surface of the fiber array unit substrate, the first angle different from the second angle.

14. The method of claim 8, further comprising sending a test signal through one of the plurality of optical fibers to a device under test.

15. An optical device comprising:
a substrate material with a first side and a second side;
a first trench in the substrate material, the first trench having a first width adjacent to the first side of the substrate material and a second width adjacent to the second side of the substrate material, the first width different from the second width; and
a first optical fiber within the first trench.

16. The optical device of claim 15, further comprising a second trench in the substrate material, the second trench having the first width adjacent to the first side of the substrate material and a third width adjacent to the second side of the substrate material, the third width being different from the first width and the second width.

17. The optical device of claim 16, further comprising a cover plate over the first trench and the second trench.

18. The optical device of claim 17, wherein the first trench is located a first distance away from a surface of the cover plate and wherein the second trench is located a second distance away from the surface of the cover plate, the first distance being different from the second distance.

19. The optical device of claim 15, wherein the first optical fiber is planar with a surface of the substrate material.

20. The optical device of claim 15, further comprising a device under test in optical communication with the first optical fiber.
